(19) United States
(12) Patent Application Publication
(10) Pub. No.: US 2026/0096387 A1
(43) Pub. Date: Apr. 2, 2026

(54) SUBSTRATE PROCESSING APPARATUS AND SUBSTRATE PROCESSING METHOD

(71) Applicant: SHIBAURA MECHATRONICS CORPORATION, Kanagawa (JP)

(72) Inventor: Takaaki TSUCHIMOCHI, Kanagawa (JP)

(21) Appl. No.: 19/341,361

(22) Filed: Sep. 26, 2025

(30) Foreign Application Priority Data
Sep. 30, 2024 (JP) 2024-171558

(51) Int. Cl. H01L 21/67

(52) U.S. Cl. CPC H10P 72/0602; H10P 72/0424; H10P 72/0604

(57) ABSTRACT

A substrate processing apparatus includes: a rotational holding unit; a bottom surface ejection nozzle; a bottom surface supply pipe; a heating unit; a flow rate adjustment unit; and a control device. The control device includes a temperature control unit that controls the flow rate adjustment unit to eject the processing liquid to a height that does not reach the bottom surface of the substrate, in a state where the rotational holding unit holds the substrate, thereby increasing a temperature of the bottom surface supply pipe, and a processing control unit that after the temperature of the bottom surface supply pipe is increased, controls the flow rate adjustment unit to eject the processing liquid to a height that reaches the bottom surface of the substrate, thereby performing a processing of the substrate.

### CROSS REFERENCES TO RELATED APPLICATIONS

This application is based on and claims priority from Japanese Patent Application No. 2024-171558, filed on September 30, 2024, with the Japan Patent Office, the disclosure of which is incorporated herein in its entirety by reference.

### TECHNICAL FIELD

The present disclosure relates to a substrate processing apparatus and a substrate processing method.

### BACKGROUND

A single-wafer substrate processing apparatus, which processes substrates such as semiconductor wafers one by one using a chemical liquid or a cleaning liquid, is widely adopted from the viewpoint of uniformity and reproducibility of the processing on each substrate. In the single-wafer substrate processing apparatus, a rotating body is rotated in the state of holding a substrate to rotate the substrate, and while rotating the substrate, the processing liquid is ejected toward the central region of the top surface of the substrate, such that the processing liquid spreads uniformly over the entire top surface of the substrate by, for example, centrifugal force, thereby processing the top surface of the substrate.

Generally, as the temperature of the processing liquid increases, the processing rate increases. Thus, the processing liquid is heated to a preset temperature. Then, the substrate processing apparatus ejects the processing liquid heated to the set temperature toward the top surface of the substrate. See, for example, Japanese Laid-Open Patent Publication No. 2012-004294.

### SUMMARY

The substrate processing apparatus may eject the processing liquid toward the bottom surface of the substrate to process the bottom surface of the substrate. The heated processing liquid flows through a supply pipe connected to an ejection nozzle, and is ejected from the ejection nozzle toward the bottom surface of the substrate. However, the temperature of the heated processing liquid may drop while the processing liquid flows through the supply pipe.

Embodiments of the present disclosure have been proposed to solve the problem above, and the object thereof is to provide a substrate processing apparatus and a substrate processing method, which suppress the drop of the temperature of the processing liquid supplied to the bottom surface of the substrate.

According to an embodiment of the present disclosure, a substrate processing apparatus includes: a rotational holder that holds and rotates a substrate; a bottom surface ejection nozzle that ejects a processing liquid toward a bottom surface of the substrate; a bottom surface supply pipe connected to the bottom surface ejection nozzle; a heater that heats the processing liquid supplied to the bottom surface supply pipe; a flow rate regulator that adjusts a flow rate of the processing liquid ejected from the bottom surface ejection nozzle; and a controller that controls the flow rate regulator. The controller includes a temperature controller that controls the flow rate regulator to eject the processing liquid to a height that does not reach the bottom surface of the substrate, in a state where the rotational holder holds the substrate, thereby increasing a temperature of the bottom surface supply pipe, and a processing controller that, after the temperature of the bottom surface supply pipe is increased, controls the flow rate regulator to eject the processing liquid to a height that reaches the bottom surface of the substrate, thereby performing a processing of the substrate.

According to an embodiment of the present disclosure, a substrate processing apparatus includes: a rotational holder that holds and rotates a substrate; a nozzle head including a recess provided to face a bottom surface of the substrate held in the rotational holder, and a liquid draining hole opened in the recess; a bottom surface ejection nozzle that is provided in the nozzle head, and ejects a processing liquid toward the bottom surface of the substrate; a bottom surface supply pipe connected to the bottom surface ejection nozzle; a heater that heats the processing liquid supplied to the bottom surface supply pipe; a flow rate regulator that adjusts a flow rate of the processing liquid ejected from the bottom surface ejection nozzle; and a controller that controls the flow rate regulator. The controller includes a temperature controller that controls the flow rate regulator such that the processing liquid ejected from the bottom surface ejection nozzle lands in the recess, thereby increasing a temperature of the bottom surface supply pipe, and a processing controller that, after the temperature of the bottom surface supply pipe is increased, controls the flow rate regulator such that the bottom surface ejection nozzle ejects the processing liquid to a height that reaches the bottom surface of the substrate, in a state where the rotational holder holds the substrate, thereby performing a processing of the substrate.

According to an embodiment of the present disclosure, a substrate processing method includes: holding a substrate; rotating the substrate; after the holding the substrate, adjusting a flow rate of a processing liquid ejected from a bottom surface ejection nozzle connected to a bottom surface supply pipe, to eject a heated processing liquid from the bottom surface supply pipe to a height that does not reach a bottom surface of the substrate, thereby increasing a temperature of the bottom surface supply pipe; and after the increasing the temperature of the bottom surface supply pipe, adjusting the flow rate of the processing liquid ejected from the bottom surface ejection nozzle, to eject the processing liquid from the bottom surface ejection nozzle to a height that reaches the bottom surface of the substrate, thereby performing a processing of the substrate.

According to an embodiment of the present disclosure, a substrate processing method includes: ejecting a heated processing liquid from a bottom surface ejection nozzle connected to a bottom surface supply pipe, thereby increasing a temperature of the bottom surface supply pipe; holding a substrate; rotating the substrate; and adjusting a flow rate of the processing liquid ejected from the bottom surface ejection nozzle, to eject the processing liquid from the bottom surface ejection nozzle to a height that reaches the bottom surface of the substrate, thereby performing a processing of the substrate. In the increasing the temperature, the flow rate of the processing liquid ejected from the bottom surface ejection nozzle is adjusted such that the processing liquid ejected from the bottom surface ejection nozzle lands in a recess in which a liquid draining hole is opened, and which faces the bottom surface of the substrate.

According to embodiments of the present disclosure, it is possible to suppress the drop of the temperature of the processing liquid supplied to the bottom surface of the substrate.

The foregoing summary is illustrative only and is not intended to be in any way restricting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a schematic side view illustrating an overall configuration of a substrate processing apparatus according to a first embodiment.

FIG. 2 is a schematic view illustrating a state where a processing liquid is ejected during a processing control, according to the first embodiment.

FIG. 3 is a plan view of a nozzle head according to the first embodiment.

FIG. 4 is a schematic view illustrating a state where the processing liquid is not ejected, according to the first embodiment.

FIG. 5 is a schematic view illustrating a state where the processing liquid is ejected during a temperature rise control, according to the first embodiment.

FIG. 6 is a flowchart illustrating a processing method according to the first embodiment.

FIG. 7 is a flowchart illustrating a processing method according to a second embodiment.

FIG. 8 is a schematic view illustrating a state where a processing liquid is ejected during a temperature rise control, according to the second embodiment.

FIG. 9 is a schematic view illustrating a configuration of a pipe according to a modification.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

### First Embodiment

Hereinafter, a first embodiment of the present disclosure will be described with reference to the drawings. The present disclosure is not limited to the embodiment described herein below.

### Overview

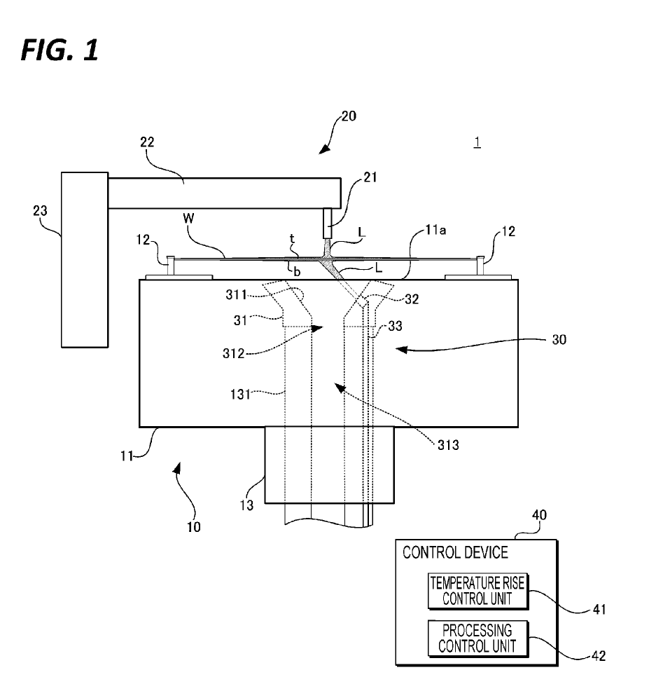

As illustrated in FIG. 1, a substrate processing apparatus 1 is an apparatus that ejects a processing liquid L onto a substrate W while rotating the substrate W in the state of holding the substrate W by a rotational holding unit 10. The substrate processing apparatus 1 ejects the processing liquid L onto the top surface "t" and the bottom surface "b" of the substrate W to perform a processing on both the top surface t and the bottom surface b of the substrate W. The processing liquid L ejected onto the top surface t and the bottom surface b of the substrate W is an etching solution, for example, an aqueous solution containing phosphoric acid.

Prior to performing the processing on the bottom surface b of the substrate W, the substrate processing apparatus 1 ejects the processing liquid L from a bottom surface ejection nozzle 32 to a height that does not reach the bottom surface b of the substrate W, to increase the temperature of a bottom surface supply pipe 33 connected to the bottom surface ejection nozzle 32. After increasing the temperature of the bottom surface supply pipe 33, the substrate processing apparatus 1 ejects the processing liquid L to a height that reaches the bottom surface b of the substrate W, to perform the processing on the bottom surface b of the substrate W.

As illustrated in FIG. 1, the substrate processing apparatus 1 includes the rotational holding unit 10, a top-surface processing liquid supply unit 20, a bottom-surface processing liquid supply unit 30, and a control device 40.

### Rotational Holding Unit

The rotational holding unit 10 rotates the substrate W while holding the substrate W. The rotational holding unit 10 includes a rotating body 11, a holding member 12, and a drive mechanism 13. The rotating body 11 is a member having a cylindrical shape, and is, for example, a rotary table. One end of the rotating body 11 is closed by a facing surface 11a. The facing surface 11a is a circular surface with a diameter larger than that of the substrate W, and faces the substrate W to be processed with a spacing from the substrate W. A through hole is formed in the center portion of the rotating body 11 to serve as a space. A holding cylinder 131 is inserted through the through hole of the rotating body 11. The holding cylinder 131 is a hollow annular member that forms a flow passage along the rotation axis of the rotating body 11. The flow passage makes up a liquid draining passage 313. The holding cylinder 131 is supported on a trestle (not illustrated). Thus, the holding cylinder 131 does not rotate in conjunction with the rotating body 11.

The holding member 12 is a holder that holds the substrate W with a spacing from the facing surface 11a of the rotating body 11. The holding member 12 is provided to protrude from the facing surface 11a of the rotating body 11. A plurality of holding members 12 are provided at equal intervals along positions corresponding to the outer peripheral edge of the substrate W. Further, the holding member 12 is provided to be movable by an open/close mechanism (not illustrated) between a closed position in contact with the outer peripheral edge of the substrate W to hold the substrate W and an open position away from the outer peripheral edge of the substrate W to release the substrate W.

The drive mechanism 13 is a drive source (e.g., a motor) that rotates the rotating body 11. The drive mechanism 13 rotates the rotating body 11 to rotate the substrate W held by the holding member 12 around the rotation axis that passes through the center of the substrate W and extends in the direction perpendicular to the top surface t (bottom surface b). The drive source is a hollow motor, through which the holding cylinder 131 is inserted in a non-contact manner. Thus, the holding cylinder 131 does not rotate.

### Top-Surface Processing Liquid Supply Unit

The top-surface processing liquid supply unit 20 supplies the processing liquid L to the top surface t of the substrate W. The top-surface processing liquid supply unit 20 includes a top surface ejection nozzle 21, an arm 22, and a movement mechanism 23.

The top surface ejection nozzle 21 is provided to be positioned above the central region of the top surface t of the substrate W, at a supply position to be described herein later. The top surface ejection nozzle 21 ejects the processing liquid L toward the central region of the top surface t of the substrate W. The top surface ejection nozzle 21 is connected to a top surface supply pipe (not illustrated). The top surface supply pipe is connected to a processing liquid supply source (not illustrated), and the top surface ejection nozzle 21 ejects the processing liquid L fed from the processing liquid supply source through the top surface supply pipe. The processing liquid L is ejected after being heated to a predetermined temperature, for example, 160 °C.

The arm 22 holds the top surface ejection nozzle 21 at the tip thereof. The movement mechanism 23 moves the arm 22 in the direction parallel to the top surface t of the substrate W, thereby moving the top surface ejection nozzle 21 in the direction parallel to the top surface t of the substrate W. By moving the arm 22, the movement mechanism 23 moves the top surface ejection nozzle 21 between the supply position, which is located above the central region of the substrate W, and a retracted position, which is retracted from above the substrate W.

Further, the top-surface processing liquid supply unit 20 includes a cleaning liquid ejection nozzle (not illustrated) to eject a cleaning liquid toward the top surface t of the substrate W. The cleaning liquid ejection nozzle for ejecting the cleaning liquid is connected to a cleaning liquid supply source (not illustrated) via a cleaning liquid supply pipe (not illustrated). Carbonated water or pure water may be used as the cleaning liquid.

### Bottom-Surface Processing Liquid Supply Unit

The bottom-surface processing liquid supply unit 30 supplies the processing liquid L to the bottom surface b of the substrate W. The bottom-surface processing liquid supply unit 30 includes a nozzle head 31, a bottom surface ejection nozzle 32, a bottom surface supply pipe 33, a processing liquid supply source 34, a heating unit 35, a pipe 36, a pump 36a, three open/close valves 37a, 37b, and 37c, a flow rate adjustment unit 38, and a cleaning liquid ejection nozzle 39.

The nozzle head 31 is provided inside the rotating body 11, and attached to the top of the holding cylinder 131. Thus, the nozzle head 31 does not rotate when the rotating body 11 rotates. The nozzle head 31 includes a recess 311 and a liquid draining hole 312.

The recess 311 is provided to face the bottom surface b of the substrate W held in the rotational holding unit 10. The recess 311 is a concave portion formed in the top surface of the nozzle head 31. The recess 311 has an inverted conical shape with its top surface opened. That is, the recess 311 has a sloping surface, and is gradually narrowed from top toward bottom. The center axis of the recess 311 is coaxial with the rotation axis of the substrate W. The recess 311 receives the processing liquid L that drops down after being ejected from the bottom surface ejection nozzle 32. The liquid draining hole 312 is formed at the lowest end of the sloping surface of the recess 311. That is, the liquid draining hole 312 is opened in the recess 311, and communicates with the recess 311. Further, the liquid draining hole 312 is connected to the upper end of the liquid draining passage 313 of the holding cylinder 131. Thus, the processing liquid L received in the recess 311 is discharged through the liquid draining hole 312 and the liquid draining passage 313.

The bottom surface ejection nozzle 32 ejects the processing liquid L toward the central region of the bottom surface b of the substrate W. The bottom surface ejection nozzle 32 is provided to be positioned below the bottom surface b of the substrate W held in the rotational holding unit 10. The bottom surface ejection nozzle 32 is disposed at a position deviated from the center of the substrate W in plan view. Thus, the bottom surface ejection nozzle 32 is disposed obliquely with respect to the rotation axis of the rotating body 11, to eject the processing liquid L to the central region of the bottom surface b of the substrate W. The bottom surface ejection nozzle 32 is provided in the recess 311 of the nozzle head 31.

The bottom surface supply pipe 33 is a flow passage through which the processing liquid L flows, and is a pipe for supplying the processing liquid L to the bottom surface ejection nozzle 32. One end of the bottom surface supply pipe 33 is connected to the lower side of the bottom surface ejection nozzle 32. The bottom surface supply pipe 33 is provided to penetrate through the thick portion of the holding cylinder 131 and extend to the outside of the rotating body 11. The other end of the bottom surface supply pipe 33 is connected to the open/close valve 37a. When the open/close valve 37a is brought to the open state, the processing liquid L is supplied to the bottom surface supply pipe 33. Then, the processing liquid L is supplied from the bottom surface supply pipe 33 to the bottom surface ejection nozzle 32, and ejected from the bottom surface ejection nozzle 32.

The processing liquid supply source 34 is, for example, a tank that stores the processing liquid L. The pipe 36 is connected to the processing liquid supply source 34. The processing liquid supply source 34 is provided with an outlet port 341 that is an opening for discharging the processing liquid L into the pipe 36, and an inlet port 342 that is an opening into which the processing liquid L flows from the pipe 36. The processing liquid supply source 34 feeds the processing liquid L to the pipe 36 through the outlet port 341. Further, the processing liquid supply source 34 receives the inflow of the processing liquid L from the pipe 36 through the inlet port 342.

The heating unit 35 heats the processing liquid L fed from the processing liquid supply source 34 to a predetermined temperature, which is a preset temperature. The predetermined temperature is the same as the temperature of the processing liquid L supplied to the top surface t of the substrate W, and is, for example, 160 °C.

The pipe 36 is a flow path through which the processing liquid L flows. The pipe 36 is a pipe for circulating the processing liquid L stored in the processing liquid supply source 34, and supplying the processing liquid L heated by the heating unit 35 to the bottom surface supply pipe 33. The pipe 36 includes a delivery pipe 361, a circulation pipe 362, a branch pipe 363, and a flow rate adjustment pipe 364.

The delivery pipe 361 is a pipe into which the processing liquid L flows from the processing liquid supply source 34. One end of the delivery pipe 361 is connected to the outlet port 341 of the processing liquid supply source 34. The other end of the delivery pipe 361 is branched and connected to the circulation pipe 362 and the branch pipe 363. The delivery pipe 361 is also connected to the flow rate adjustment pipe 364. The pump 36a and the heating unit 35 are provided in the middle of the delivery pipe 361. In the delivery pipe 361, the heating unit 35 is disposed on the downstream side relative to the pump 36a. The pump 36a feeds the processing liquid L stored in the processing liquid supply source 34 to the delivery pipe 361. The processing liquid L flowing through the delivery pipe 361 by the operation of the pump 36a is heated to the predetermined temperature by the heating unit 35.

The circulation pipe 362 is a pipe for returning the processing liquid L fed from the processing liquid supply source 34, to the processing liquid supply source 34. One end of the circulation pipe 362 is connected to the delivery pipe 361. The other end of the circulation pipe 362 is connected to the inlet port 342 of the processing liquid supply source 34. Thus, the processing liquid L fed from the processing liquid supply source 34 may circulate by flowing through the delivery pipe 361 and the circulation pipe 362. The open/close valve 37b is provided in the middle of the circulation pipe 362. When the processing liquid L is not ejected from the bottom surface ejection nozzle 32, the open/close valve 37b is brought to the open state to circulate the processing liquid L through the circulation pipe 362. Even during the time when the processing liquid L is not ejected from the bottom surface ejection nozzle 32, the processing liquid L is maintained at the predetermined temperature by circulating while being heated by the heating unit 35. Meanwhile, when the processing liquid L is ejected from the bottom surface ejection nozzle 32, the open/close valve 37b is brought to the closed state.

The branch pipe 363 is a pipe that supplies the processing liquid L to the bottom surface supply pipe 33. One end of the branch pipe 363 is connected to the delivery pipe 361. The other end of the branch pipe 363 is connected to the open/close valve 37a. Thus, the processing liquid L fed from the processing liquid supply source 34 may flow through the delivery pipe 361 and the branch pipe 363, and be supplied to the bottom surface supply pipe 33 via the open/close valve 37a. By the opening and closing of the open/close valve 37a, the supply and stop of the processing liquid L from the branch pipe 363 to the bottom surface supply pipe 33 are controlled.

The flow rate adjustment pipe 364 is a pipe for adjusting the flow rate of the processing liquid L supplied from the branch pipe 363 to the bottom surface supply pipe 33. One end of the flow rate adjustment pipe 364 is connected to the delivery pipe 361, at a position downstream of the heating unit 35. The other end of the flow rate adjustment pipe 364 is connected to the circulation pipe 362, at a position downstream of the open/close valve 37b. The flow rate adjustment pipe 364 is a flow passage through which the processing liquid L flows when being ejected from the bottom surface ejection nozzle 32. The flow rate adjustment pipe 364 is provided with the open/close valve 37c and the flow rate adjustment unit 38. In the flow rate adjustment pipe 364, the flow rate adjustment unit 38 is provided on the downstream side relative to the open/close valve 37c. The open/close valve 37c is brought to the open state when the processing liquid L is ejected from the bottom surface ejection nozzle 32, and to the closed state when the processing liquid L is not ejected.

The flow rate adjustment unit 38 is, for example, a needle valve, and adjusts the flow rate of the processing liquid L ejected from the bottom surface ejection nozzle 32. Specifically, the open/close valves 37a and 37c are brought to the open state, to adjust the flow rate of the processing liquid L flowing through the flow rate adjustment pipe 364, thereby adjusting the flow rate of the processing liquid L flowing through the branch pipe 363 and the bottom surface supply pipe 33 to be ejected from the bottom surface ejection nozzle 32. The ejection height of the processing liquid L is determined by the flow rate of the processing liquid L ejected from the bottom surface ejection nozzle 32. The ejection height of the processing liquid L refers to the highest position of the trajectory of the processing liquid L ejected upward (diagonally upward in the present embodiment) from the bottom surface ejection nozzle 32.

In the present embodiment, the open/close valve 37a is provided outside the rotating body 11. Accordingly, the heating unit 35 that heats the processing liquid L and the pipe 36 that supplies the heated processing liquid L to the bottom surface supply pipe 33 are also provided outside the rotating body 11. That is, the processing liquid L heated in the heating unit 35 passes through the bottom surface supply pipe 33, which has the length equal to or longer than at least the length of the rotating body 11 in the direction of the rotation axis, and then, ejected from the bottom surface ejection nozzle 32.

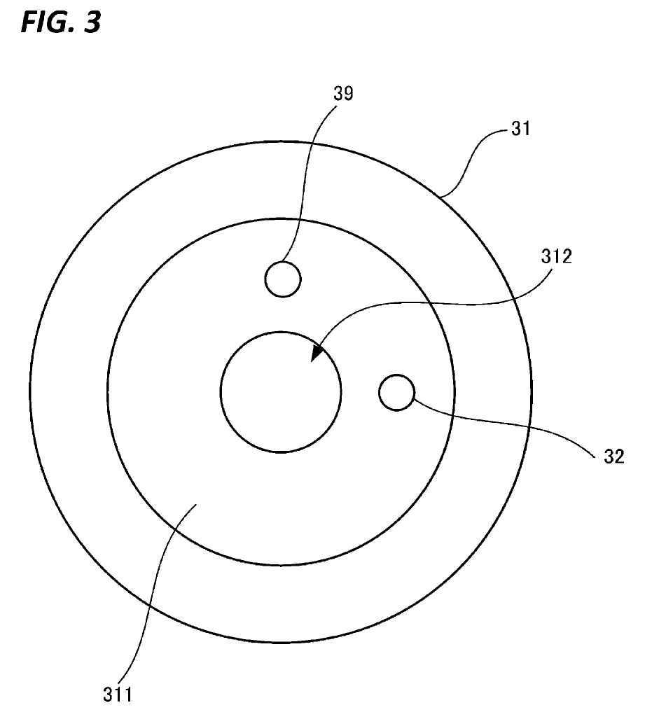

The cleaning liquid ejection nozzle 39 ejects the cleaning liquid toward the bottom surface b of the substrate W. The cleaning liquid ejection nozzle 39 is connected to a cleaning liquid supply source (not illustrated) via a cleaning liquid supply pipe (not illustrated). Carbonated water or pure water may be used as the cleaning liquid. The cleaning liquid ejection nozzle 39 is disposed at a position deviated from the center of the substrate W in plan view. Thus, the cleaning liquid ejection nozzle 39 is disposed obliquely with respect to the rotation axis of the rotating body 11, to eject the cleaning liquid to the central region of the bottom surface b of the substrate W. The cleaning liquid ejection nozzle 39 is provided in the recess 311 of the nozzle head 31. As illustrated in FIG. 3, the cleaning liquid ejection nozzle 39 is provided at a position that does not face the bottom surface ejection nozzle 32, in the recess 311. That is, in plan view, the cleaning liquid ejection nozzle 39 is provided at a position away from the bottom surface ejection nozzle 32 and the straight line passing through the center of the recess 311 (the liquid draining hole 312).

### Control Device

The control device 40 controls each component of the substrate processing apparatus 1. In order to implement the various functions of the substrate processing apparatus 1, the control device 40 includes a processor that executes programs, a memory that stores various types of information such as programs and operation conditions, and a drive circuit that drives each component. That is, the control device 40 controls, for example, the rotational holding unit 10, the top-surface processing liquid supply unit 20, and the bottom-surface processing liquid supply unit 30.

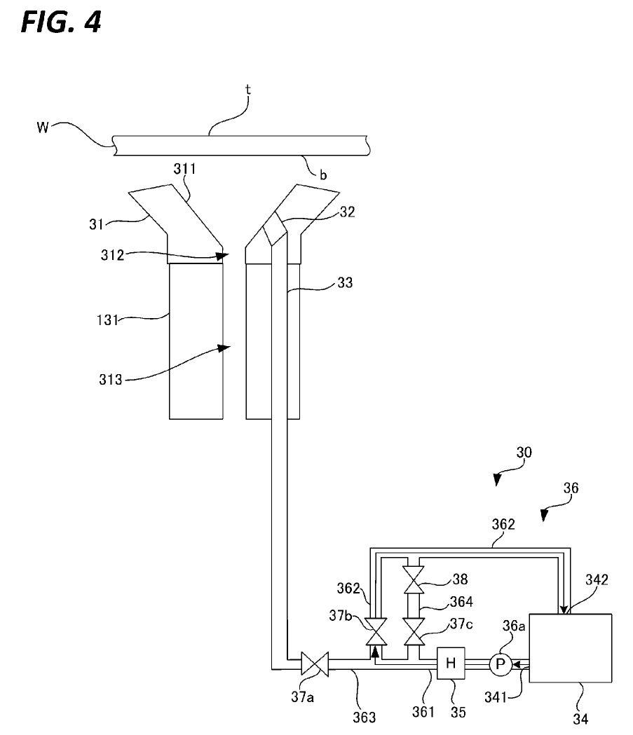

The control device 40 controls the open/close valves 37a, 37b, and 37c and the flow rate adjustment unit 38 of the bottom-surface processing liquid supply unit 30, to control the ejection and stop of the processing liquid L from the bottom surface ejection nozzle 32 and the ejection height of the processing liquid L. When the processing liquid L is not ejected from the bottom surface ejection nozzle 32, the control device 40 controls the open/close valves 37a and 37c to the closed state, and the open/close valve 37b to the open state. Then, as illustrated in FIG. 4, the processing liquid L circulates through the delivery pipe 361 and the circulation pipe 362. Thus, the processing liquid L circulating in the pipe 36 (the delivery pipe 361 and the circulation pipe 362) is heated by the heating unit 35, and maintained at the predetermined temperature.

Meanwhile, when the processing liquid L is ejected from the bottom surface ejection nozzle 32, the control device 40 controls the open/close valve 37b to the closed state, and the open/close valves 37a and 37c to the open state. By controlling the open/close valves 37a, 37b, and 37c in this manner, the processing liquid L flows from the branch pipe 363 to the bottom surface supply pipe 33, and ejected from the bottom surface ejection nozzle 32.

The control device 40 includes a temperature rise control unit 41 and a processing control unit 42. The temperature rise control unit 41 performs a temperature rise control, and the processing control unit 42 performs a processing control. The temperature rise control and the processing control are identical in that both eject the processing liquid L from the bottom surface ejection nozzle 32, but different in terms of the ejection height of the processing liquid L.

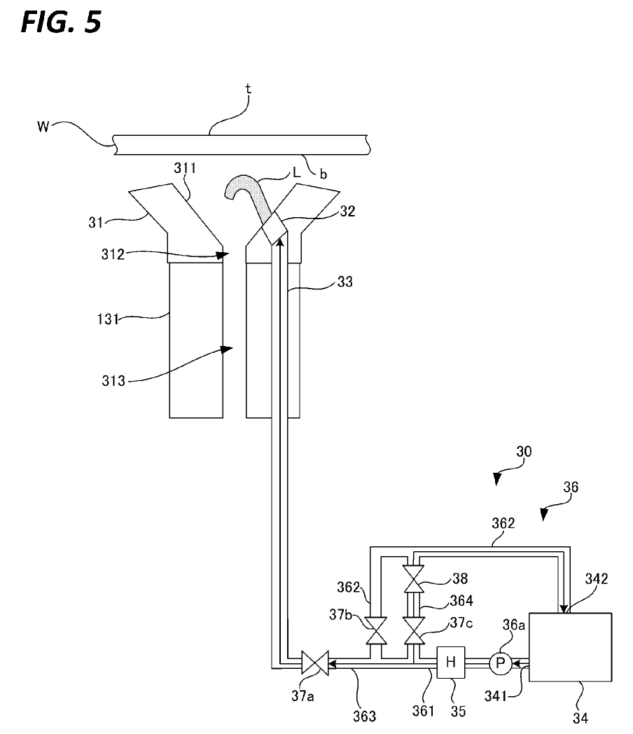

The temperature rise control is a control for increasing the temperature of the bottom surface supply pipe 33 to be substantially equal to the temperature of the processing liquid L ejected during the processing control. As illustrated in FIG. 5, the temperature rise control causes the processing liquid L to be ejected to a height at which the processing liquid L does not reach the bottom surface b of the substrate W. Thus, the temperature rise control unit 41 controls the flow rate adjustment unit 38 such that the ejection height of the processing liquid L does not reach the bottom surface b of the substrate W. In the state of the temperature rise control, the processing on the bottom surface b of the substrate W does not start because the processing liquid L does not reach the bottom surface b of the substrate W. Further, it is desirable that in the temperature rise control, the temperature rise control unit 41 controls the flow rate by the flow rate adjustment unit 38 to cause the processing liquid L ejected from the bottom surface ejection nozzle 32 to land in the recess 311 of the nozzle head 31. By controlling the flow rate in this manner, the processing liquid L may be prevented from scattering onto, for example, the rotating body 11.

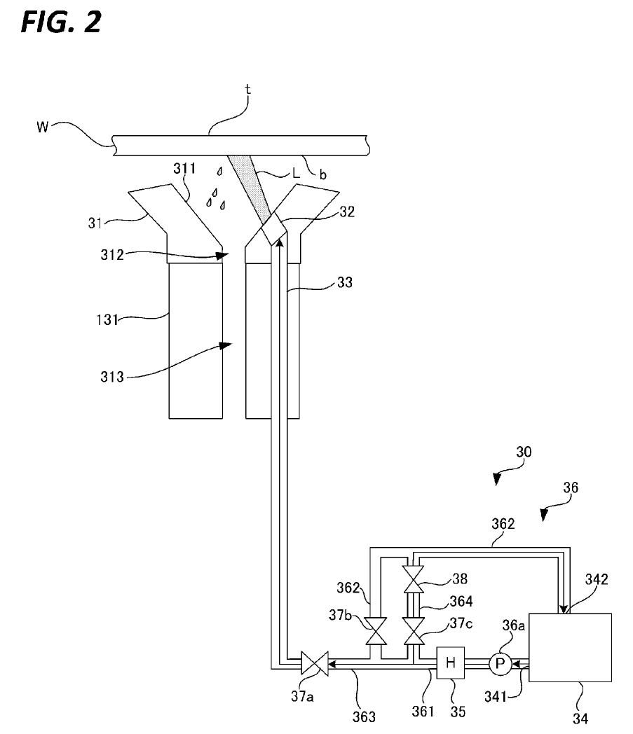

As illustrated in FIG. 2, the processing control is a control for ejecting the processing liquid L to the height at which the processing liquid L reaches the bottom surface b of the substrate W, to perform the processing on the bottom surface b of the substrate W. The processing control unit 42 controls the flow rate adjustment unit 38 such that the flow rate becomes greater than the flow rate during the temperature rise control, and the ejection height of the processing liquid L becomes the height that reaches the bottom surface b of the substrate W.

### Processing Method

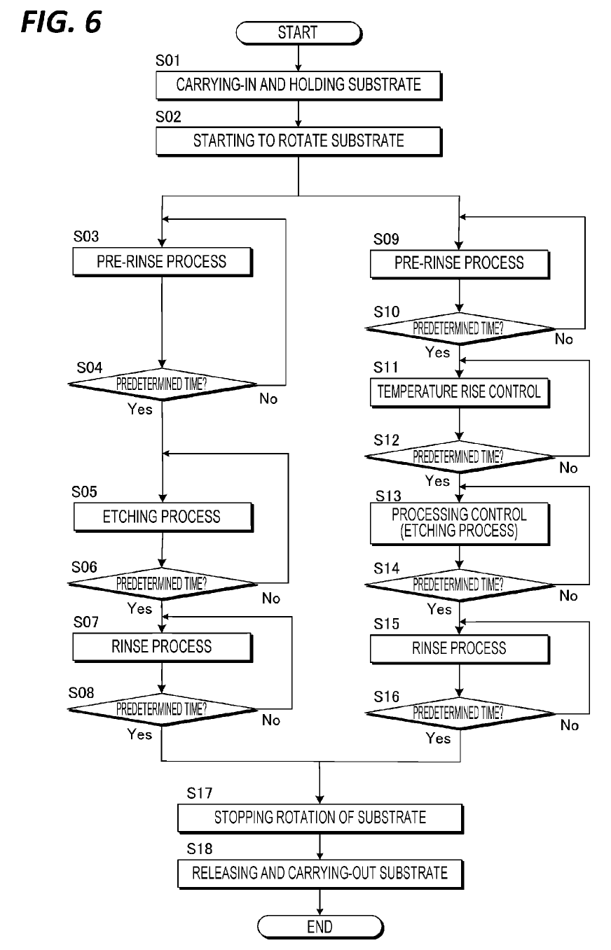

The operation of the substrate processing apparatus 1 according to the present embodiment described above will be described with reference to the flowchart of FIG. 6, in addition to FIGS. 1 to 5. A substrate processing method, which processes the substrate W according to the process described below, is also an aspect of the present disclosure.

As illustrated in FIG. 4, the control device 40 controls the open/close valves 37a and 37c to the closed state, and the open/close valve 37b to the open state in advance, such that the processing liquid L circulates in the pipe 36. That is, the processing liquid L passes through the heating unit 35, and is maintained at the predetermined temperature in advance.

The substrate W to be processed is a substrate on which a film such as a silicon nitride film or a silicon oxide film is formed. In the present embodiment, an etching process is performed on both the top surface t and the bottom surface b of the substrate W. First, the holding member 12 moves to the open position, so that the substrate W mounted on the hand of a transfer robot is carried in. Then, the holding member 12 moves to the closed position, so that the outer peripheral edge of the substrate W is held by the holding member 12 (step S01). Then, the rotating body 11 rotates, and the substrate W rotates (step S02).

Then, the process is divided into steps S03 to S08 for processing the top surface t of the substrate W and steps S09 to S16 for processing the bottom surface b of the substrate W. In the present embodiment, since the top surface t and the bottom surface b of the substrate W are processed simultaneously as illustrated in FIG. 1, steps S03 to S08 and steps S09 to S16 are performed in parallel.

First, the flow of the processing on the top surface t of the substrate W will be described. A pre-rinse process is performed on the top surface t of the substrate W (step S03). The pre-rinse process is a preparatory step for the etching process on the substrate W. The top-surface processing liquid supply unit 20 ejects the cleaning liquid from the cleaning liquid ejection nozzle toward the top surface t of the substrate W, to start the pre-rinse process on the top surface t of the substrate W. The pre-rinse process is performed until a predetermined time elapses (step S04: No). The predetermined time is, for example, 30 seconds.

When the predetermined time elapses (step S04: Yes), the etching process is performed on the top surface t of the substrate W (step S05). The top-surface processing liquid supply unit 20 ejects the processing liquid L from the top surface ejection nozzle 21 toward the top surface t of the substrate W, to start the etching process on the top surface t of the substrate W. The etching process is performed until a predetermined time elapses (step S06: No). When the predetermined time elapses (step S06: Yes), the ejection of the processing liquid L from the top surface ejection nozzle 21 is stopped, and the etching process ends.

Finally, the cleaning liquid is ejected onto the top surface t of the substrate W, to perform a rinse process (step S07). That is, the cleaning liquid is ejected from the cleaning liquid ejection nozzle toward the top surface t of the substrate W, to start the rinse process on the top surface t of the substrate W. The rinse process is performed until a predetermined time elapses (step S08: No). When the predetermined time elapses (step S08: Yes), the rinse process ends, and the processing on the top surface t of the substrate W ends.

Meanwhile, the processing on the bottom surface b of the substrate W is performed simultaneously in parallel with the processing on the top surface t of the substrate W. The processing on the bottom surface b of the substrate W is performed by transitioning to step S09 when the rotation of the substrate W starts (step S02). In the processing on the bottom surface b of the substrate W, the pre-rinse process and the temperature rise control are performed in parallel with the preparatory step for the top surface t of the substrate W (pre-rinse process).

First, the cleaning liquid is supplied to the bottom surface b of the substrate W, to perform the pre-rinse process on the bottom surface b of the substrate W (step S09). The cleaning liquid ejection nozzle 39 of the bottom-surface processing liquid supply unit 30 ejects the cleaning liquid onto the bottom surface b of the substrate W, to perform the pre-rinse process on the bottom surface b of the substrate W. At this time, as illustrated in FIG. 4, the control device 40 controls the open/close valves 37a and 37c to the closed state, and the open/close valve 37b to the open state, such that the processing liquid L circulates in the delivery pipe 361 and the circulation pipe 362. That is, the processing liquid L passes through the heating unit 35, and is maintained at the predetermined temperature. The pre-rinse process is performed until a predetermined time elapses (step S10: No). The predetermined time is, for example, 15 seconds.

When the predetermined time elapses (step S10: Yes), the temperature rise control unit 41 performs the temperature rise control (step S11). That is, as illustrated in FIG. 5, the temperature rise control unit 41 controls the open/close valves 37a and 37c to the open state, and the open/close valve 37b to the closed state. Further, the temperature rise control unit 41 controls the flow rate adjustment unit 38 such that the ejection height of the processing liquid L does not reach the bottom surface b of the substrate W.

The processing liquid L heated by the heating unit 35 and maintained at the predetermined temperature passes through the bottom surface supply pipe 33 and moves toward the bottom surface ejection nozzle 32. As the heated processing liquid L flows through the bottom surface supply pipe 33, the temperature of the bottom surface supply pipe 33 increases by heat conduction from the processing liquid L. In the temperature rise control, the etching process on the bottom surface b of the substrate W is not performed, because the processing liquid L is ejected only to the height that does not reach the bottom surface b of the substrate W.

The temperature rise control is performed until a predetermined time elapses to the extent that the temperature of the bottom surface supply pipe 33 becomes substantially equal to the temperature of the processing liquid L ejected during the processing control (step S12: No). The predetermined time is, for example, 15 seconds. When the temperature rise control is performed for the predetermined time (step S12: Yes), the temperature of the bottom surface supply pipe 33 increases to be substantially equal to the temperature of the processing liquid L circulating in the pipe 36. That is, even though the processing liquid L heated to the predetermined temperature passes through the bottom surface supply pipe 33, the temperature of the processing liquid L does not decrease.

The pre-rinse process on the bottom surface b of the substrate W (step S09) and the temperature rise control (step S11) are performed in parallel with the pre-rinse process on the top surface t of the substrate W (step S03). That is, the sum of the time for the pre-rinse process on the bottom surface b of the substrate W (step S09) and the time for the temperature rise control (step S11) corresponds to the time for the pre-rinse process on the top surface t of the substrate W (step S03).

As described above, each of the pre-rinse process (step S09) and the temperature rise control (step S11) in the processing on the bottom surface b is performed for 15 seconds, such that the sum of the time for the pre-rinse process and the time for the temperature rise control is equal to the time for the preparatory step on the top surface t (pre-rinse process). However, the time is not limited as long as the temperature of the bottom surface supply pipe 33 may be increased to become substantially equal to the temperature of the processing liquid L ejected during the processing control. For example, the pre-rinse process (step S09) may be performed for 10 seconds, and the temperature rise control (step S11) may be performed for 20 seconds. Further, while the time for the entire preparatory step is set to 30 seconds, the time for the preparatory step may be shorter or longer than 30 seconds.

After the temperature rise control is performed for the predetermined time, the processing control unit 42 performs the processing control (step S13). The bottom-surface processing liquid supply unit 30 ejects the processing liquid L from the bottom surface ejection nozzle 32 to the bottom surface b of the substrate W, to perform the etching process on the bottom surface b of the substrate W. As illustrated in FIG. 2, the processing control unit 42 controls the open/close valves 37a and 37c to the open state and the open/close valve 37b to the closed state, and further, controls the flow rate adjustment unit 38 such that the ejection height of the processing liquid L reaches the bottom surface b of the substrate W.

The processing control is performed consecutively after the temperature rise control. The terms "performed consecutively" indicate that the temperature rise control transitions to the processing control without stopping the ejection of the processing liquid L from the bottom surface ejection nozzle 32. That is, it indicates that during the transition from the temperature rise control to the processing control, there is no time when the processing liquid L does not flow in the bottom surface supply pipe 33. The temperature rise control unit 41 does not bring the open/close valve 37a to the closed state even after the temperature rise control ends, and the processing control unit 42 controls the flow rate adjustment unit 38 while maintaining the open/close valve 37a in the open state. Thus, the temperature of the bottom surface supply pipe 33 that has been increased through the temperature rise control may be suppressed from decreasing during the transition from the temperature rise control to the processing control.

The processing control (etching process) is performed until a predetermined time elapses (step S14: No). When the predetermined time elapses (step S14: Yes), the ejection of the processing liquid L from the bottom surface ejection nozzle 32 is stopped. The processing control unit 42 brings the open/close valves 37a and 37c to the closed state and the open/close valve 37b to the open state, so that the ejection of the processing liquid L from the bottom surface ejection nozzle 32 is stopped, and the processing liquid L circulates in the pipe 36. Then, the etching process on the bottom surface b of the substrate W ends. The etching process on the bottom surface b of the substrate W (step S13) is performed in parallel with the etching process on the top surface t of the substrate W (step S05).

Finally, the cleaning liquid is ejected onto the bottom surface b of the substrate W, to perform a rinse process (step S15). That is, the cleaning liquid is ejected onto the bottom surface b of the substrate W from the cleaning liquid ejection nozzle 39 of the bottom-surface processing liquid supply unit 30, to start the rinse process on the bottom surface b of the substrate W. The rinse process is performed until a predetermined time elapses (step S16: No). When the predetermined time elapses (step S16: Yes), the rinse process ends, and the processing on the bottom surface b of the substrate W ends.

When the rinse process on the top surface t of the substrate W and the rinse process on the bottom surface b of the substrate W end (step S08: Yes, step S16: Yes), the rotation of the rotating body 11 stops, and the rotation of the substrate W stops (step S17). When the rotation of the substrate W stops, the hand of the transfer robot is inserted below the substrate W, the holding member 12 is brought to the open position to release the substrate W, and the substrate W is placed on the hand of the transfer robot and carried out of the substrate processing apparatus 1 (step S18).

### Effects

(1) As described above, the substrate processing apparatus 1 of the present embodiment includes: the rotational holding unit 10 that holds and rotates the substrate W; the bottom surface ejection nozzle 32 that ejects the processing liquid L toward the bottom surface b of the substrate W; the bottom surface supply pipe 33 connected to the bottom surface ejection nozzle 32; the heating unit 35 that heats the processing liquid L supplied to the bottom surface supply pipe 33; the flow rate adjustment unit 38 that adjusts the flow rate of the processing liquid L ejected from the bottom surface ejection nozzle 32; and the control device 40 that controls the flow rate adjustment unit 38. The control device 40 includes: the temperature rise control unit 41 that controls the flow rate adjustment unit 38 to eject the processing liquid L to the height that does not reach the bottom surface b of the substrate W, in the state where the rotational holding unit 10 holds the substrate W, thereby increasing the temperature of the bottom surface supply pipe 33; and the processing control unit 42 that, after the temperature of the bottom surface supply pipe 33 increases, controls the flow rate adjustment unit 38 to eject the processing liquid L to the height that reaches the bottom surface b of the substrate W, thereby processing the substrate W.

The substrate processing method according to the present embodiment includes: a holding process of holding the substrate W; a rotating process of rotating the substrate W; a temperature increasing process of, after the holding process, adjusting the flow rate of the processing liquid L ejected from the bottom surface ejection nozzle 32 connected to the bottom supply pipe 33, to eject the heated processing liquid L from the bottom surface ejection nozzle 32 to the height that does not reach the bottom surface b of the substrate W, thereby increasing the temperature of the bottom surface supply pipe 33; and a processing process of, after the temperature increasing process, processing the substrate W by adjusting the flow rate of the processing liquid L ejected from the bottom surface ejection nozzle 32 to eject the processing liquid L from the bottom surface ejection nozzle 32 to the height that reaches the bottom surface b of the substrate W.

In this manner, in the stage before performing the processing of the substrate W, the temperature of the bottom surface supply pipe 33 may be increased through the temperature rise control by the temperature rise control unit 41. Further, in the temperature rise control, since the ejection height of the processing liquid L ejected from the bottom surface ejection nozzle 32 does not reach the bottom surface b of the substrate W, the processing liquid L is not supplied to the substrate W. Therefore, the processing on the bottom surface b of the substrate W with the processing liquid L is not performed, so that it is possible to prevent the processing of the substrate W from being performed in the state of low processing rate.

The processing on the bottom surface b of the substrate W is performed through the processing control by the processing control unit 42. At this time, since the temperature of the bottom surface supply pipe 33 has been increased by the temperature rise control, it is possible to suppress the drop of the temperature of the processing liquid L supplied to the bottom surface b of the substrate W during the processing control. Therefore, the processing on the bottom surface b of the substrate W may be performed while maintaining the high processing rate.

Further, since the temperature rise control is performed in the state where the substrate W is held, the processing control may be performed immediately after the temperature rise control. Therefore, it is possible to suppress the drop of the increased temperature of the bottom surface supply pipe 33 during the transition from the temperature rise control to the processing control.

(2) The substrate processing apparatus 1 further includes the nozzle head 31 including the recess 311 provided to face the bottom surface b of the substrate W and the liquid draining hole 312 opened in the recess 311. The bottom surface ejection nozzle 32 is provided in the nozzle head 31, and the temperature rise control unit 41 controls the flow rate adjustment unit 38 such that the processing liquid L ejected from the bottom surface ejection nozzle 32 lands in the recess 311. Therefore, the processing liquid L may be prevented from scattering onto each component of the substrate processing apparatus 1 such as the rotating body 11, so that the processing liquid L may be prevented from adhering to the substrate W from each component.

(3) The processing control unit 42 performs the processing of the substrate W by controlling the flow rate adjustment unit 38 without stopping the ejection of the processing liquid L, after the control of the flow rate adjustment unit 38 by the temperature rise control unit 41. That is, the processing liquid L flows through the bottom surface supply pipe 33 even during the transition from the temperature rise control to the processing control. Thus, it is possible to suppress the drop of the increased temperature of the bottom surface supply pipe 33 during the transition from the temperature rise control to the processing control. As a result, it is possible to more effectively suppress the drop of the temperature of the processing liquid L during the processing control.

(4) The processing liquid L is an etching solution. Thus, the temperature of the etching solution may be suppressed from dropping during the processing control for the bottom surface b of the substrate W. As a result, the processing on the bottom surface b of the substrate W may be performed while maintaining the high etching rate.

(5) The substrate processing apparatus 1 further includes the top surface ejection nozzle 21 that ejects the processing liquid L toward the top surface t of the substrate W, and the processing control unit 42 ejects the processing liquid L from the top surface ejection nozzle 21. Thus, both the top surface t and the bottom surface b of the substrate W are processed in parallel. When the temperature of the processing liquid L supplied to the bottom surface b of the substrate W is lower than the temperature of the processing liquid L supplied to the top surface t, the heat from the processing liquid L supplied to the top surface t is transferred to the processing liquid L supplied to the bottom surface b through the substrate W by heat conduction. In this case, the temperature of the processing liquid L supplied to the top surface t may decrease at the area of the top surface t that corresponds to the area of the bottom surface b to which the processing liquid L is ejected. When the temperature of the processing liquid L supplied to the corresponding area of the top surface t decreases, the temperature distribution of the processing liquid L supplied to the top surface t becomes non-uniform, resulting in a non-uniform processing rate in the plane of the top surface t.

Meanwhile, in the present embodiment, the temperature of the bottom surface supply pipe 33 is increased by the temperature rise control, and during the processing control, the drop of the temperature of the processing liquid L ejected to the bottom surface b of the substrate W is suppressed. Therefore, the temperature of the processing liquid L ejected to the top surface t of the substrate W is suppressed from decreasing due to the processing liquid L ejected to the bottom surface b of the substrate W. As a result, the temperature distribution of the processing liquid L ejected to the top surface t of the substrate W becomes uniform, and the processing rate in the plane of the top surface t is maintained.

(6) The temperature of the processing liquid L supplied to the bottom surface supply pipe 33 through the control of the flow rate adjustment unit 38 by the temperature rise control unit 41 is equal to or higher than the temperature of the processing liquid L supplied to the bottom surface supply pipe 33 through the control of the flow rate adjustment unit 38 by the processing control unit 42. In the present embodiment, the temperature of the processing liquid L supplied to the bottom surface supply pipe 33 through the temperature rise control and the temperature of the processing liquid L supplied to the bottom surface supply pipe 33 through the processing control are the same predetermined temperature. Thus, the temperature of the bottom surface supply pipe 33 may be increased quickly, so that the efficiency of the temperature rise control is improved. Further, since the temperature of the bottom surface supply pipe 33 may be increased to become substantially equal to the temperature of the processing liquid L ejected during the processing control, it is possible to suppress the drop of the temperature of the processing liquid L passing through the bottom surface supply pipe 33.

(7) The temperature rise control unit 41 controls the flow rate adjustment unit 38 until the temperature of the bottom surface supply pipe 33 or the temperature of the processing liquid L flowing through the bottom surface supply pipe 33 becomes equal to or higher than the predetermined temperature. In the present embodiment, the temperature rise control is performed for the predetermined time until the temperature of the bottom surface supply pipe 33 becomes substantially equal to the temperature of the processing liquid L ejected during the processing control. Therefore, the temperature of the bottom surface supply pipe 33 may be increased to become substantially equal to the temperature of the processing liquid L ejected during the processing control, so that it is possible to suppress the drop of the temperature of the processing liquid L passing through the bottom surface supply pipe 33.

### Second Embodiment

A substrate processing apparatus 1 according to a second embodiment of the present disclosure will be described with reference to the drawings. The same configuration and functions as those of the first embodiment will be denoted by the same reference numerals, and detailed descriptions thereof will be omitted. In the first embodiment, the temperature rise control is performed in the state where the substrate W is held and rotates after being carried in. However, in the second embodiment, the temperature rise control is performed before the substrate W is carried in.

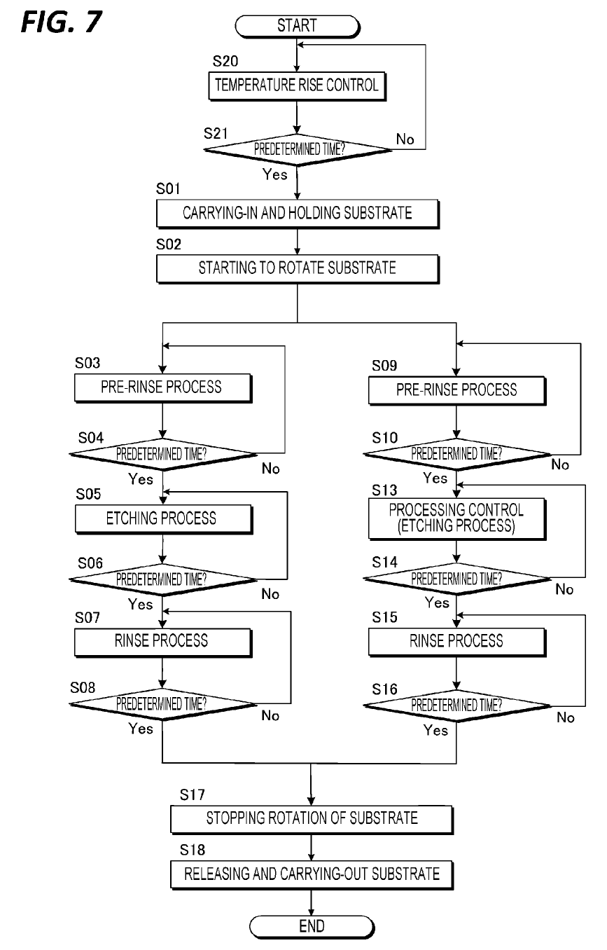

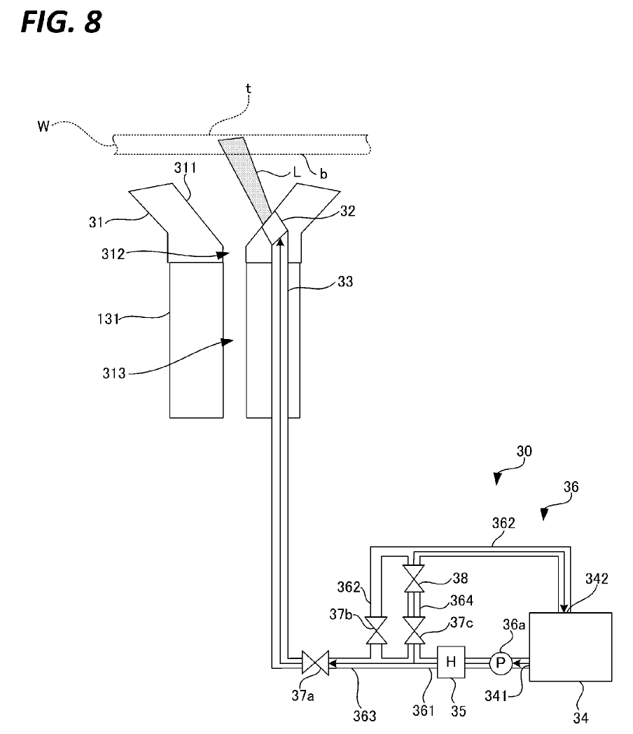

That is, as illustrated in FIG. 7, the substrate processing apparatus 1 first performs the temperature rise control by the temperature rise control unit 41 of the control device 40 (step S20). That is, the temperature of the bottom surface supply pipe 33 is increased in the state where the holding member 12 does not hold the substrate W. As illustrated in FIG. 8, the temperature rise control unit 41 may control the flow rate adjustment unit 38 to eject the processing liquid L above the height that reaches the bottom surface b of the substrate W, assuming that the substrate W is held. Even though the control device 40 controls the flow rate adjustment unit 38 in this manner, the processing of the substrate W does not start, because the substrate W is not held by the holding member 12. FIG. 8 represents the substrate W with a dotted line to depict the ejection height of the processing liquid L, although the substrate W is not actually present.

The temperature rise control unit 41 controls the flow rate adjustment unit 38 such that the ejected processing liquid L lands in the recess 311 of the nozzle head 31. That is, the processing liquid L ejected from the bottom surface ejection nozzle 32 during the temperature rise control is received by the recess 311, passes through the liquid draining hole 312, and is discharged through the liquid draining passage 313. The control of flow rate in the flow rate adjustment unit 38 may be performed based on, for example, the angle of the bottom surface ejection nozzle 32 or the size of the recess 311.

The temperature rise control is performed until a predetermined time elapses (step S21: No). When the predetermined time elapses (step S21: Yes), the substrate W is carried in, the outer peripheral edge of the substrate W is held by the holding member 12 (step S01), the rotating body 11 rotates, and the substrate W rotates (step S02). Then, as in the first embodiment, the etching process is performed on both the top surface t and the bottom surface b of the substrate W. In the processing on the bottom surface b of the substrate W, the temperature rise control has already been performed, and thus, the processing control, i.e., the etching process is performed (step S13) immediately after the pre-rinse process is performed on the substrate W (step S09). When the processing on both the top surface t and the bottom surface b of the substrate W is completed, the rotation of the substrate W stops (step S17), and the substrate W is released and carried out of the substrate processing apparatus 1 (step S18).

As described above, the substrate processing apparatus 1 of the present embodiment includes: the rotational holding unit 10 that holds and rotates the substrate W; the nozzle head 31 including the recess 311 provided to face the bottom surface b of the substrate W held in the rotational holding unit 10 and the liquid draining hole 312 opened in the recess 311; the bottom surface ejection nozzle 32 that ejects the processing liquid L toward the bottom surface b of the substrate W; the bottom surface supply pipe 33 connected to the bottom surface ejection nozzle 32; the heating unit 35 that heats the processing liquid L supplied to the bottom surface supply pipe 33; the flow rate adjustment unit 38 that adjusts the flow rate of the processing liquid L ejected from the bottom surface ejection nozzle 32; and the control device 40 that controls the flow rate adjustment unit 38. The control device 40 includes: the temperature rise control unit 41 that controls the flow rate adjustment unit 38 to cause the processing liquid L ejected from the bottom surface ejection nozzle 32 to land in the recess 311, thereby increasing the temperature of the bottom surface supply pipe 33; and the processing control unit 42 that after the temperature of the bottom surface supply pipe 33 is increased, controls the flow rate adjustment unit 38 to cause the bottom surface ejection nozzle 32 to eject the processing liquid L to the height that reaches the bottom surface b of the substrate 311, in the state where the rotational holding unit 10 holds the substrate W, thereby processing the substrate W.

The substrate processing method of the present embodiment includes: a temperature increasing process of increasing the temperature of the bottom surface supply pipe 33 by ejecting the heated processing liquid L from the bottom surface ejection nozzle 32 connected to the bottom surface supply pipe 33; a holding process of holding the substrate W; a rotating process of rotating the substrate W; and a processing process of performing the processing of the substrate W by adjusting the flow rate of the processing liquid L ejected from the bottom surface ejection nozzle 32, to eject the processing liquid L from the bottom surface ejection nozzle 32 to the height that reaches the bottom surface b of the substrate W. In the temperature increasing process, the flow rate of the processing liquid L ejected from the bottom surface ejection nozzle 32 is adjusted such that the processing liquid L ejected from the bottom surface ejection nozzle 32 lands in the recess 311 in which the liquid draining hole 312 is formed, and which faces the bottom surface b of the substrate W.

Therefore, the temperature of the bottom surface supply pipe 33 may be increased during the temperature rise control, and the temperature of the processing liquid L may be suppressed from dropping during the processing control. Further, during the temperature rise control, the flow rate of the processing liquid L ejected from the bottom surface ejection nozzle 32 is adjusted such that the processing liquid L lands in the recess 311 of the nozzle head 31. Therefore, the processing liquid L may be prevented from scattering onto components such as the rotating body 11, so that the contamination of the components of the substrate processing apparatus 1 may be prevented.

### Modifications

(1) The bottom-surface processing liquid supply unit 30 may include a flow rate detection unit that detects the flow rate of the processing liquid L ejected from the bottom surface ejection nozzle 32. The flow rate detection unit may be provided in the bottom surface supply pipe 33. Then, the temperature rise control unit 41 controls the flow rate adjustment unit 38 based on the flow rate of the processing liquid L detected by the flow rate detection unit. Thus, when the flow rate of the processing liquid L is greater than a predetermined value, the temperature rise control unit 41 may perform a control to reduce the flow rate of the processing liquid L ejected from the bottom surface ejection nozzle 32 by the flow rate adjustment unit 38. When the flow rate of the processing liquid L is less than the predetermined value, the temperature rise control unit 41 may perform a control to increase the flow rate of the processing liquid L ejected from the bottom surface ejection nozzle 32 by the flow rate adjustment unit 38. Therefore, in the temperature rise control, while effectively increasing the temperature of the bottom surface supply pipe 33, the ejection height of the processing liquid L may be more accurately controlled to the height that does not reach the bottom surface b of the substrate W or the height at which the processing liquid L lands in the recess 311 of the nozzle head 31.

Not only the temperature rise control unit 41, but also the processing control unit 42 may control the flow rate adjustment unit 38 based on the detection result of the flow rate detection unit. Thus, the flow rate of the processing liquid L may be more accurately controlled during the processing control as well. Therefore, the flow rate of the processing liquid L supplied to the bottom surface b of the substrate W may be accurately controlled, so that the processing of the substrate W may be performed.

(2) The bottom-surface processing liquid supply unit 30 may include a temperature detection unit that detects the temperature of the processing liquid L or the bottom surface supply pipe 33. The temperature detection unit may be provided in the bottom surface supply pipe 33. Then, the temperature rise control unit 41 terminates the temperature rise control when the temperature detected by the temperature detection unit reaches a predetermined temperature (the same temperature as the temperature of the processing liquid L heated by the heating unit 35 and flowing through the pipe 36). Therefore, the temperature rise control may be performed efficiently, so that the processing efficiency is improved.

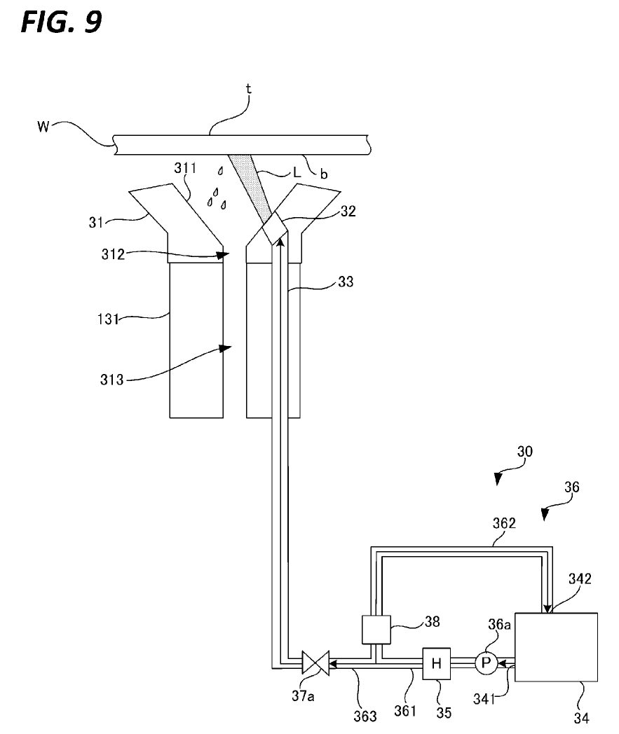

(3) The flow rate adjustment unit 38 is not limited to a needle valve. The flow rate adjustment unit 38 may be any device capable of adjusting the flow rate, and may be, for example, a mass flow controller. In this case, as illustrated in FIG. 9, the pipe 36 may not include the flow rate adjustment pipe 364. In this case, the circulation pipe 362 is provided with the flow rate adjustment unit 38, instead of the open/close valve 37b. As a result, the pipe 36 may be downsized and simplified.

(4) While the processing control unit 42 controls the open/close valves 37a and 37c to the open state and the open/close valve 37b to the closed state during the processing control, it may control the open/close valve 37a to the open state and the open/close valves 37b and 37c to the closed state. That is, the open/close valve 37c may function as the flow rate adjustment unit 38 that adjusts the flow rate of the processing liquid L ejected from the bottom surface ejection nozzle 32. For example, the inner diameter of the flow rate adjustment pipe 364 may be adjusted such that when the open/close valves 37a and 37c are in the open state, and the open/close valve 37b is in the closed state, the ejection height of the processing liquid L becomes the height that does not reach the bottom surface b of the substrate W. In this case, when the open/close valve 37a is in the open state, and the open/close valves 37b and 37c are in the closed state, the ejection height of the processing liquid L becomes the height that reaches the bottom surface b of the substrate W.

(5) In the first embodiment above, the processing control is performed consecutively after the temperature rise control without stopping the ejection of the processing liquid L. However, the temperature rise control unit 41 may stop the ejection of the processing liquid L once after the temperature rise control, and then, the processing control by the processing control unit 42 may be performed.

(6) In the first embodiment above, the temperature rise control (step S11) is performed after the pre-rinse process (step S09). However, the pre-rinse process (step S09) and the temperature rise control (step S11) may be performed in parallel. That is, while ejecting the cleaning liquid from the cleaning liquid ejection nozzle 39 toward the bottom surface b of the substrate W, the processing liquid L may be ejected from the bottom surface ejection nozzle 32 to the height that does not reach the bottom surface b of the substrate W. Here, as described above, the cleaning liquid ejection nozzle 39 is provided in the recess 311 at a position that does not face the bottom surface ejection nozzle 32 (see FIG. 3). Therefore, the pre-rinse process (step S09) and the temperature rise control (step S11) may be performed in parallel without causing an interference between the cleaning liquid ejected from the cleaning liquid ejection nozzle 39 and the processing liquid L ejected from the bottom surface ejection nozzle 32.

(7) When a plurality of substrates W is processed, based on elapsed time from the processing control on an N-th substrate W, time for the temperature rise control on an (N+1)-th substrate W may be changed. That is, when the elapsed time from the processing control on the N-th substrate W is short, the time for the temperature rise control on the (N+1)-th substrate W is reduced, and when the elapsed time from the processing control on the N-th substrate W is long, the time for the temperature rise control on the (N+1)-th substrate W is increased. Therefore, the temperature rise control may be performed based on the temperature of the bottom surface supply pipe 33 that decreases with the elapsed time from the processing control, so that the temperature of the bottom surface supply pipe 33 may be efficiently increased.

(8) In the embodiment above, the processing liquid L ejected by the temperature rise control and the processing control is the etching solution. However, the processing liquid L may not be the etching solution. The processing liquid L ejected by the temperature rise control and the processing liquid L ejected by the processing control may be different.

(9) The substrate processing apparatus 1 is not limited to the apparatus that performs the etching process using the etching solution. The substrate processing apparatus 1 may be applied to any apparatus capable of processing the bottom surface b of the substrate W using the processing liquid L that needs to be heated in advance.

(10) The temperature of the processing liquid L supplied to the bottom surface supply pipe 33 by the temperature rise control may not be the same as the temperature of the processing liquid L supplied to the bottom surface supply pipe 33 by the processing control. For example, the temperature of the processing liquid L supplied to the bottom surface supply pipe 33 by the temperature rise control may be higher than the temperature of the processing liquid L supplied to the bottom surface supply pipe 33 by the processing control. Therefore, the temperature of the bottom surface supply pipe 33 may be increased quickly, so that the efficiency of the temperature rise control is improved. Further, in this case, the processing liquid L supplied to the bottom surface supply pipe 33 by the temperature rise control may be different from the processing liquid L supplied to the bottom surface supply pipe 33 by the processing control. Further, since the temperature of the bottom surface supply pipe 33 may be increased to be higher than the temperature of the processing liquid L ejected by the processing control, it is possible to effectively suppress the drop of the temperature of the processing liquid L ejected from the bottom surface ejection nozzle 32 during the processing control.

(11) The temperature rise control unit 41 may increase the temperature of the bottom surface supply pipe 33 until the temperature of the processing liquid L flowing through the bottom surface supply pipe 33 becomes substantially equal to the temperature of the processing liquid L ejected during the processing control. In the embodiment above, the temperature rise control unit 41 performs the temperature rise control until the temperature of the bottom surface supply pipe 33 becomes substantially equal to the temperature of the processing liquid L ejected during the processing control. However, the temperature rise control may be performed until the temperature of the bottom surface supply pipe 33 becomes higher than the temperature of the processing liquid L ejected during the processing control. When the temperature rise control and the processing control are not performed consecutively, the increased temperature of the bottom surface supply pipe 33 may decrease during the time between the temperature rise control and the processing control. Thus, the temperature of the bottom surface supply pipe 33 is increased by the temperature rise control, taking into account the decreasing temperature as well. As a result, the temperature of the processing liquid L ejected during the processing control may be suppressed from dropping from the predetermined temperature.

(12) In the embodiment above, both the top surface t and the bottom surface b of the substrate W are processed in parallel. However, only the bottom surface b of the substrate W may be processed. Further, the top surface t of the substrate W may be processed, and then, the bottom surface b of the substrate W may be processed. In this case, after the processing on the top surface t of the substrate W ends, the bottom surface b of the substrate W may be processed without reversing the substrate W, so that the processing efficiency is improved.

### Other Embodiments

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be restricting, with the true scope and spirit being indicated by the following claims.

What is claimed is:

1. A substrate processing apparatus comprising:
a rotational holder configured to hold and rotate a substrate;
a bottom surface ejection nozzle configured to eject a processing liquid toward a bottom surface of the substrate;
a bottom surface supply pipe connected to the bottom surface ejection nozzle;
a heater configured to heat the processing liquid supplied to the bottom surface supply pipe;
a flow rate regulator configured to adjust a flow rate of the processing liquid ejected from the bottom surface ejection nozzle; and
a controller configured to control the flow rate regulator,
wherein the controller includes
a temperature controller configured to control the flow rate regulator to eject the processing liquid to a height that does not reach the bottom surface of the substrate, in a state where the rotational holder holds the substrate, thereby increasing a temperature of the bottom surface supply pipe, and
a processing controller configured to, after the temperature of the bottom surface supply pipe is increased, control the flow rate regulator to eject the processing liquid to a height that reaches the bottom surface of the substrate, thereby performing a processing of the substrate.

2. A substrate processing apparatus comprising:
a rotational holder configured to hold and rotate a substrate;
a nozzle head including a recess provided to face a bottom surface of the substrate held in the rotational holder, and a liquid draining hole opened in the recess;
a bottom surface ejection nozzle provided in the nozzle head, and configured to eject a processing liquid toward the bottom surface of the substrate;
a bottom surface supply pipe connected to the bottom surface ejection nozzle;
a heater configured to heat the processing liquid supplied to the bottom surface supply pipe;
a flow rate regulator configured to adjust a flow rate of the processing liquid ejected from the bottom surface ejection nozzle; and
a controller configured to control the flow rate regulator,
wherein the controller includes
a temperature controller configured to control the flow rate regulator such that the processing liquid ejected from the bottom surface ejection nozzle lands in the recess, thereby increasing a temperature of the bottom surface supply pipe, and
a processing controller configured to, after the temperature of the bottom surface supply pipe is increased, control the flow rate regulator such that the bottom surface ejection nozzle ejects the processing liquid to a height that reaches the bottom surface of the substrate, in a state where the rotational holder holds the substrate, thereby performing a processing of the substrate.

3. The substrate processing apparatus according to claim 1, further comprising:
a nozzle head including a recess provided to face the bottom surface of the substrate, and a liquid draining hole opened in the recess,
wherein the bottom surface ejection nozzle is provided in the nozzle head, and
the temperature controller controls the flow rate regulator such that the processing liquid ejected from the bottom surface ejection nozzle lands in the recess.

4. The substrate processing apparatus according to claim 1, further comprising:
a flow rate detector provided in the bottom surface supply pipe, and configured to detect the flow rate of the processing liquid,
wherein the temperature controller controls the flow rate regulator based on the flow rate detected by the flow rate detector.

5. The substrate processing apparatus according to claim 1, further comprising:
a temperature detector configured to detect the temperature of the bottom surface supply pipe or a temperature of the processing liquid flowing through the bottom surface supply pipe,
wherein the temperature controller controls the flow rate regulator based on the temperature detected by the temperature detector, to terminate the increasing of the temperature of the bottom surface supply pipe.

6. The substrate processing apparatus according to claim 1, wherein after the control of the flow rate regulator by the temperature controller, the processing controller controls the flow rate regulator without stopping the ejection of the processing liquid to perform the processing of the substrate.

7. The substrate processing apparatus according to claim 1, wherein the processing liquid is an etching solution.

8. The substrate processing apparatus according to claim 1, further comprising:
a top surface ejection nozzle configured to eject the processing liquid toward a top surface of the substrate,
wherein the processing controller causes the processing liquid to be ejected from the top surface ejection nozzle.

9. The substrate processing apparatus according to claim 1, wherein a temperature of the processing liquid supplied to the bottom surface supply pipe through the control of the flow rate regulator by the temperature controller is equal to or higher than a temperature of the processing liquid supplied to the bottom surface supply pipe through the control of the flow rate regulator by the processing controller.

10. The substrate processing apparatus according to claim 1, wherein the temperature controller controls the flow rate regulator until the temperature of the bottom surface supply pipe or a temperature of the processing liquid flowing through the bottom surface supply pipe becomes equal to or higher than a predetermined temperature.

11. A substrate processing method comprising:
holding a substrate;
rotating the substrate;
after the holding the substrate, adjusting a flow rate of a processing liquid ejected from a bottom surface ejection nozzle connected to a bottom surface supply pipe, to eject a heated processing liquid from the bottom surface ejection nozzle to a height that does not reach a bottom surface of the substrate, thereby increasing a temperature of the bottom surface supply pipe; and
after the increasing the temperature of the bottom surface supply pipe, adjusting the flow rate of the processing liquid ejected from the bottom surface ejection nozzle, to eject the processing liquid from the bottom surface ejection nozzle to a height that reaches the bottom surface of the substrate, thereby performing a processing of the substrate.
